(19) United States
(12) Patent Application Publication
(10) Pub. No.: US 2025/0303446 A1
(43) Pub. Date: Oct. 2, 2025

(54) ULTRASONIC TRANSDUCER AND METHOD FOR PREPARING THE SAME

(71) Applicant: SHENZHEN PENINSULA MEDICAL GROUP, Shenzhen (CN)

(72) Inventors: Pengbo LIU, Shenzhen (CN); Yanan LI, Shenzhen (CN); Xiaobing LEI, Shenzhen (CN); Qiaohong LI, Shenzhen (CN); Renshuang SUN, Shenzhen (CN); Yujia PENG, Shenzhen (CN)

(73) Assignee: SHENZHEN PENINSULA MEDICAL GROUP, Shenzhen (CN)

(21) Appl. No.: 19/012,788

(22) Filed: Jan. 7, 2025

Related U.S. Application Data
(63) Continuation of application No. PCT/CN2024/110329, filed on Aug. 7, 2024.

(30) Foreign Application Priority Data
Mar. 29, 2024 (CN) 202410384567.7

(51) Int. Cl. B06B 1/06; H10N 30/063; H10N 30/87; H10N 30/88

(52) U.S. Cl. CPC B06B 1/0629; H10N 30/063; H10N 30/872; H10N 30/883

(57) ABSTRACT

Disclosed are an ultrasonic transducer and a method for preparing the same. The ultrasonic transducer includes: an integrated circuit (IC) substrate, an element array layer, and an insulating layer. The IC substrate, the element array layer and the insulating layer are stacked in sequence. The element array layer includes a plurality of transducer units. The transducer unit includes a first electrode layer and a piezoelectric material layer. The transducer unit is welded and connected to the IC substrate via metal bumps carried on the first electrode layer. The insulating layer includes a plurality of vibration structure units carried thereon.

### CROSS-REFERENCE TO RELATED APPLICATIONS

This application is a continuation application of International Application No. PCT/CN2024/110329, filed on Aug. 7, 2024, which claims priority to Chinese Patent Application No. 202410384567.7, filed on Mar. 29, 2024. All of the aforementioned applications are incorporated herein by reference in their entireties.

### TECHNICAL FIELD

The present application relates to the technical field of ultrasonic transducers, and in particular to an ultrasonic transducer and a method for preparing the same.

### BACKGROUND

With the development of technology, ultrasonic transducers are increasingly being used in various fields. Currently, the technologies used to connect electrodes of miniaturized two-dimensional ultrasonic transducers are mainly wire bonding or through silicon via (TSV).

Wire bonding is the process of connecting the transducer array element and the connector terminal with gold wire at the electrode end of the manufactured miniaturized two-dimensional array ultrasonic transducer. The positive and negative electrodes of the transducer are respectively connected to the bonding wire extracted from two opposite surfaces of the transducer. The TSV process uses dry or wet etching methods to extract the positive and negative electrodes of the ultrasonic transducer array element onto the same surface, by using the through holes filled with conductive materials, electrical connection of the positive and negative electrodes with the circuit board at the bottom is achieved.

However, the wire bonding process method requires the introduction of signal transmission lines. The characteristic impedance and signal attenuation of the signal transmission lines themselves will bring unexpected signal interference. The TSV process is not only complex and costly, but also requires a large amount of welding to achieve the connection between the electrode and the through hole, which is prone to misalignment, short circuits, cold solder joints, etc., thereby reducing the yield of the finished product.

Therefore, how to improve the reliability and quality of signal transmission while ensuring lower costs and higher yields is an urgent problem to be solved by those skilled in the art.

### SUMMARY

The main objective of the present application is to provide an ultrasonic transducer and a method for preparing the same, aiming to solve the technical problem in the related art that it is impossible to ensure high signal transmission reliability and signal quality while ensuring low cost and high yield.

In order to achieve the above technical problems, the present application provides an ultrasonic transducer, including: an integrated circuit (IC) substrate; an element array layer; and an insulating layer.

In an embodiment, the IC substrate, the element array layer and the insulating layer are stacked in sequence, the element array layer includes a plurality of transducer units; the transducer unit includes a first electrode layer and a piezoelectric material layer; the transducer unit is welded and connected to the IC substrate via a metal bump carried on the first electrode layer; and the insulating layer includes a plurality of vibration structure units carried thereon.

In an embodiment, the plurality of vibration structure units are provided with a plurality of back cavity grooves along a direction perpendicular to the element array layer; and a dimension of the back cavity groove gradually decreases from an opening to a bottom of the back cavity groove.

In an embodiment, the plurality of vibration structure units are spaced apart uniformly along a direction of the insulating layer.

In an embodiment, the plurality of vibration structure units have a same shape, and a dimension of each vibration structure unit is identical along a direction perpendicular to the element array layer.

In an embodiment, the ultrasonic transducer further includes: a porous heat dissipation substrate, where a surface of the IC substrate away from the metal bump is fixedly connected to the porous heat dissipation substrate.

In an embodiment, the IC substrate is an application specific integrated circuit (ASIC) substrate.

In an embodiment, the ultrasonic transducer further includes: electronic insulating glue, where the electronic insulating glue is filled between adjacent transducer units.

In an embodiment, the ultrasonic transducer further includes: an acoustic impedance matching layer, where the acoustic impedance matching layer at least covers an outer surface of the insulating layer.

In an embodiment, the acoustic impedance matching layer further includes a conductive glue layer; and the insulating layer is configured to insulate the element array layer from the conductive glue layer.

In an embodiment, bottom electrodes of the plurality of transducer units are connected to the IC substrate via at least one of coaxial cables, gold wire bonding, and through silicon via direct connection.

The present application further provides a method for preparing an ultrasonic transducer, including:

providing a piezoelectric material layer on an insulating layer, where the insulating layer includes a plurality of vibration structure units carried thereon;

plating a first electrode layer on a first surface of the piezoelectric material layer, where the first surface is a surface of the piezoelectric material layer away from the insulating layer;

cutting the first surface plated with the first electrode layer to obtain a plurality of array elements arranged in an array;

converting the array elements into the transducer units by placing metal bumps on the array elements to obtain an element array layer; and

welding the element array layer to an IC substrate via the metal bumps.

In an embodiment, the metal bump is connected to the IC substrate by reflow soldering.

The ultrasonic transducer provided by the present application includes: an IC substrate, an element array layer and an insulating layer; the element array layer includes a plurality of transducer units; the transducer unit includes a first electrode layer and a piezoelectric material layer; the transducer unit is welded and connected to the IC substrate via metal bumps carried on the first electrode layer; the insulating layer includes a plurality of vibration structure units carried thereon. In the present application. the transducer unit is flipped, and the first electrode layer with metal bumps is in turn welded in direct contact with the IC substrate below, which has a strong structure, simple process and low cost, and at the same time ensures that the signal transmission path is the shortest, the interference is less, and the attenuation is lower, so that the signal transmission reliability is greatly improved and the signal quality is greatly improved. The present application further provides a method for preparing an ultrasonic transducer having the above-mentioned beneficial effects.

### BRIEF DESCRIPTION OF THE DRAWINGS

In order to more clearly illustrate the technical solutions in the embodiments of the present application or in the related art, drawings used in the embodiments or in the related art will be briefly described below. Obviously, the drawings in the following description are only some embodiments of the present application. It will be apparent to those skilled in the art that other figures can be obtained according to the structures shown in the drawings without creative work.

FIG. 1 is a schematic structural diagram of an ultrasonic transducer according to an embodiment of the present application.

FIG. 2 is a schematic structural diagram of the ultrasonic transducer according to an embodiment of the present application.

FIG. 3 is a schematic flowchart of a method for preparing the ultrasonic transducer according to an embodiment of the present application.

FIG. 4 is a process structure diagram of the method for preparing the ultrasonic transducer according to an embodiment of the present application.

FIG. 5 is a schematic diagram of a partial structure of the ultrasonic transducer according to an embodiment of the present application.

### DETAILED DESCRIPTION OF THE EMBODIMENTS

In order to make the purpose, technical solutions and advantages of the present application clearer, the technical solutions in the present application will be clearly and completely described below in conjunction with the accompanying drawings of the present application. Obviously, the described embodiments are part of the embodiments of the present application, not all of the embodiments. Based on the embodiments of the present application, all other embodiments obtained by those skilled in the art without creative efforts fall within the scope of the present application.

The present application provides an ultrasonic transducer, and a schematic structural diagram of an ultrasonic transducer according to an embodiment is shown in FIG. 1. The ultrasonic transducer includes: an integrated circuit (IC) substrate 100, an element array layer 200 and an insulating layer 300.

The IC substrate 100, the element array layer 200 and the insulating layer 300 are stacked in sequence.

The element array layer 200 includes a plurality of transducer units 210.

The transducer unit 210 includes a first electrode layer 212, a piezoelectric material layer 211, and a second electrode layer (not shown in FIG. 1).

The transducer unit 210 is connected to the IC substrate 100 by welding through the metal bumps 213 carried on the first electrode layer 212.

The insulating layer 300 includes a plurality of vibration structure units 310 carried thereon.

The transducer unit 210 needs to be connected to the circuit where the IC substrate 100 is located to obtain the corresponding signal, so it is connected to the external circuit through the upper electrode and the lower electrode. Since the transducer unit 210 is flipped in the present application, the first electrode layer 212 is instead at the bottom. As shown in FIG. 5, which shows a partial enlarged schematic diagram of the ultrasonic transducer, where the first electrode layer 212 (generally the positive electrode) is in direct contact with the IC substrate 100. Correspondingly, the second electrode layer 214 in FIG. 5 is connected to the substrate 400 (generally a printed circuit board (PCB) substrate) where the IC substrate 100 is located through a cable.

The ultrasonic transducer provided by the present application may be a two-dimensional array ultrasonic transducer, or other types of two-dimensional focused ultrasonic transducers, such as 1.25 D, 1.5 D and 1.75 D arrays, or a one-dimensional linear array ultrasonic transducer array.

In an embodiment, the piezoelectric material layer 211 can be at least one of a piezoelectric ceramic layer, a piezoelectric single crystal layer, a piezoelectric composite material layer, a silicon-based capacitive micromachined ultrasonic transducer (CMUT) layer, and a silicon-based piezoelectric micromachined ultrasonic transducer (PMUT) layer. It can also be further combined with composite ceramic technology to form a 1-3 type composite material structure by molding the piezoelectric ceramic raw materials, which can be selected according to actual conditions. The insulating layer 300 can also be an insulating layer based on cavity-silicon on insulator (CSOI), which can also be selected according to actual conditions, which is not limited here.

In an embodiment, the lower electrodes of the plurality of transducer units 210 are connected to the IC substrate 100 through at least one of coaxial cables, gold wire bonding, and through-silicon via direct connection. The lower electrodes of the plurality of transducer units 210 are connected to each other and directly connected to the IC substrate 100 through at least one of coaxial cables, gold wire bonding, and through-silicon via direct connection, which can greatly simplify the circuit structure of the device, reduce production costs, and improve the working stability of the device. In a specific embodiment, the lower electrode is connected to the ground electrode connection point of the IC substrate 100. By controlling the electrical signals of the upper electrodes of different transducer units, the voltage difference between the upper and lower electrodes of the corresponding transducer units can be controlled respectively, thereby controlling the output of ultrasonic energy.

In another embodiment of the present application, the lower electrodes of different transducer units may also be separated from each other and respectively connected to different electrical connection points of the IC substrate to achieve independent, more complex but more precise control.

In an embodiment, the ultrasonic transducer further includes a porous heat dissipation substrate 400.

The surface of the IC substrate 100 away from the metal bump 213 is fixedly connected to the porous heat dissipation substrate 400.

The ultrasonic transducer can be integrated on other structures, and the integrated structure can provide a substrate 400 for the ultrasonic transducer to be placed. In an embodiment, the substrate 400 where the IC substrate 100 is located is a porous heat dissipation substrate 400, that is, there are multiple heat dissipation holes on the substrate 400, which can greatly improve the heat dissipation efficiency, so that the ultrasonic transducer can be kept at a suitable working temperature for a long time, thereby extending the continuous working time of the ultrasonic transducer.

In an embodiment, the IC substrate 100 is an application specific integrated circuit (ASIC) substrate. The ASIC substrate 100 has better customization potential and higher access efficiency, is suitable for simultaneous multi-point access, easily provides very high bandwidth, and is easy to expand performance and is not easily restricted by other hardware in the circuit, thereby further broadening the scope of application of the ultrasonic transducer.

In addition, the ultrasonic transducer further includes electronic insulating glue, which is filled between adjacent transducer units 210.

The multiple transducer units 210 in the element array layer 200 should be controlled independently. Therefore, in order to avoid short circuit between adjacent transducer units 210 (mainly short circuit of the upper electrode) due to factors such as vibration during operation, electronic insulating glue is filled between adjacent transducer units 210 in this embodiment. The electronic insulating glue can be low-temperature electronic insulating glue, which remains solid at the normal operating temperature of the ultrasonic transducer.

In order to ensure the insulation between adjacent transducer units 210, the gap between the element array layer 200 and the IC substrate 100 can be completely filled with electronic insulating glue to ensure that the transducer units 210 are completely filled with electronic insulating glue. Other methods can also be used to ensure the insulation between adjacent transducer units 210, such as reserving enough space and ensuring insulation in a non-contact manner, which is not limited in the present application and can be selected according to actual needs.

In an embodiment, the ultrasonic transducer further includes an acoustic impedance matching layer.

The acoustic impedance matching layer at least covers the outer surface of the insulating layer 300.

The acoustic impedance matching layer matches the acoustic impedance of the object of the ultrasonic transducer so as to conduct the vibration energy with maximum efficiency.

In an embodiment, an acoustic impedance matching layer is further added to the ultrasonic transducer to match the surface to which the ultrasonic transducer is to be attached. In this embodiment, the outermost layer of the acoustic impedance matching layer is limited to at least one of an epoxy resin layer and a vulcanized rubber layer. The epoxy resin layer and the vulcanized rubber layer have better biocompatibility and can be applied to a large number of applications of ultrasonic transducers in the human body, further broadening the scope of application of the ultrasonic transducer. Furthermore, the acoustic impedance matching layer further includes a conductive glue layer.

The insulating layer 300 insulates the element array layer 200 from the conductive glue layer.

The conductive glue layer and the second electrode layer 214 of the element array layer 200 are isolated by the insulating layer 300, thereby avoiding the risk of short circuit caused by contact between the two, especially avoiding the risk of short circuit that may be caused during the vibration of the insulating layer 300. At the same time, a potential difference is formed between the second electrode layer 214 and the conductive glue layer, amplifying the vibration effect, thereby increasing the ultrasonic output energy. The conductive glue layer can be a conductive silver glue layer or a graphite powder glue layer.

In an embodiment, the conductive glue layer is directly sprayed on the surface of the insulating layer 300. In other words, the conductive glue layer is the layer closest to the insulating layer 300 in the acoustic impedance matching layer, so as to further improve the ultrasonic sensitivity effect and output energy.

When the conductive glue layer is sprayed on the surface of the insulating layer 300 by a spraying process, part of the conductive adhesive may reach the element array layer 200 below the insulating layer 300 through the edge position. If it is not pre-treated, there may be a risk of short circuit. In this regard, the above-mentioned embodiment uses electronic insulating glue to fill the element array layer for insulation treatment, which can avoid the conductive glue layer and the element array layer 200 from forming a short circuit. In addition, the edge position can also be cut off by edge cutting to avoid the conductive glue layer and the element array layer from shorting.

In an embodiment of the present application, an oxide layer is further provided on the surface of the insulating layer 300 close to the element array layer 200, and this structure can further improve the electrical insulation performance of the insulating layer 300. Specifically, the oxide layer can be a layer structure obtained by oxidation treatment on the surface of the original insulating layer 300. When the original insulating layer 300 is a silicon layer, the oxide layer is a silicon oxide layer, which is specifically obtained by oxidation treatment on the surface of a silicon wafer.

A specific embodiment of an ultrasonic transducer is given below. In an embodiment, a semiconductor flip chip ball grid array (FCBGA) is used. In the flip chip package FCBGA, a bump (i.e., the metal bump 213 mentioned above) is grown on CSOI or piezoelectric ceramic-piezoelectric single crystal. The bump is a copper column or a solder ball. The spacing between each array element of the phased array transducer is related to the beam deflection angle of phased imaging, and theoretically needs to satisfy the following formula (1):

Pitch≤½λ=½ (c/f); (1)

Among them, c is the speed of sound in the object. If the ultrasonic transducer is a medical or skin beauty ultrasonic transducer, c is the speed of sound corresponding to human tissue, f is the center frequency of the corresponding transmission frequency, and λ is the wavelength, which is approximately equal to c/f. In practical applications, considering the realization of the process, the spacing is 0.5 λ˜1 λ. The broadband transducer can appropriately increase the array element spacing, and 0.7˜0.9 times the wavelength is appropriate. In intracardiac ultrasound applications, the center frequency is approximately 6.5 MHz. After calculation, the size of the copper column or each unit is less than 200 um. If it is made by manual welding or using the traditional flexible printed circuit (FPC) hot pressing process, the solder joints are prone to cold soldering, dislocation, short circuit, etc.; and the solder joints themselves will also introduce additional interference signals, a signal transmission cable is therefore required, and the characteristic impedance of the cable itself and the attenuation of the cable will also bring additional interference signals.

In the present application. a metal bump is grown on the front side (upper electrode) of the transducer unit by using a flip-chip process, and the array element is reflow-soldered to electrically connect the array element to the bottom IC. This can reduce the size of the solder joints and increase the additional capacitance of the signal transmission, thereby reducing the attenuation of the signal transmission, improving the signal quality, and greatly improving the reliability of the signal transmission.

The ultrasonic transducer provided by the present application includes: an IC substrate 100, an element array layer 200 and an insulating layer 300 stacked in sequence. The element array layer 200 includes a plurality of transducer units 210; the transducer unit 210 includes a first electrode layer 212 and a piezoelectric material layer 211; the transducer unit 210 is welded and connected to the IC substrate 100 via a metal bump 213 on the first electrode layer 212; and the insulating layer 300 includes a plurality of vibration structure units 310 carried thereon. In the present application, the transducer unit 210 is flipped, and the first electrode layer 212 with the metal bump 213 is in turn welded in direct contact with the IC substrate 100 below, which has a firm structure, simple process and low cost, and at the same time ensures that the signal transmission path is the shortest, the interference is less, and the attenuation is lower, so that the transmission reliability of the signal is greatly improved and the signal quality is greatly improved.

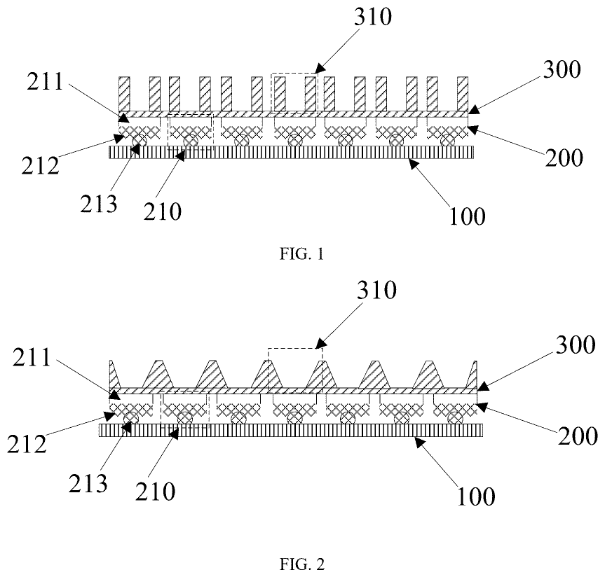

Based on the above embodiments, the vibration structure unit 310 is further improved, as shown in FIG. 2, which includes an IC substrate 100, an element array layer 200 and an insulating layer 300 stacked in sequence.

The element array layer 200 includes a plurality of transducer units 210.

The transducer unit 210 includes a first electrode layer 212 and a piezoelectric material layer 211.

The transducer unit 210 is welded and connected to the IC substrate 100 via the metal bumps 213 carried on the first electrode layer 212.

The insulating layer 300 includes a plurality of vibration structure units 310 carried thereon.

The plurality of vibration structure units 310 are provided with a plurality of back cavity grooves along a direction perpendicular to the element array layer 200.

The dimension of the back cavity groove gradually decreases from the opening to the bottom of the groove.

In this embodiment, the structure of the back cavity groove on the back of the vibration structure unit 310 is defined, and the remaining structures refer to the description of the above embodiment and will not be repeated herein.

In an embodiment, there are a plurality of back cavity grooves formed along with the vibration structure units 310, and the dimension of the back cavity groove gradually decreases from the opening to the bottom of the groove. As shown in FIG. 2, the cross-section of the side wall of the back cavity groove in FIG. 2 is a right-angle trapezoid. The back cavity groove structure with a dimension gradually increasing from the bottom of the groove to the outside can make the energy of the vibration structure unit 310 more concentrated, avoid excessive energy being consumed by the ultrasonic transducer, increase the sensitivity of the signal, and further ensure the singleness of the vibration mode without interference, so as to improve the final output vibration in line with the design expectations.

In addition, the main vibration structure of the vibration structure unit 310 is a thin film at the bottom of the groove. When etching the insulating layer 300, the etching depth is controlled to avoid penetrating the insulating layer to obtain a thin film at the bottom of the groove. Compared with a straight-cylindrical etching structure (i.e., the groove dimension is basically the same from the opening to the bottom of the groove), the angle between the side wall of the groove with a gradually reduced dimension and the bottom of the groove is an obtuse angle. When the thin film at the bottom of the groove vibrates, the structural stress at the angle is small, which can allow the film to have a larger amplitude, thereby improving the output of ultrasonic energy. Moreover, compared with the solution in which the angle between the side wall of the groove and the bottom of the groove is a right angle, the groove-type structure with a gradually reduced dimension can improve the vibration mode of a single array element during vibration.

The side wall cross-section of the vibration structure unit 310 can be a trapezoidal shape or an irregular shape. For example, the side wall can be an arc surface, which can be selected according to actual conditions and is not limited in the present application.

In this embodiment, the groove bottom and the groove wall are made of the same material and are obtained by etching from a wafer. In other embodiments of the present application, the thin film at the groove bottom can also be an additional thin film layer obtained by deposition on a wafer.

The opening direction of the back cavity groove is perpendicular to the direction of the element array layer 200 and faces outwards. For details, please refer to the relevant technology and the present application will not elaborate on it here.

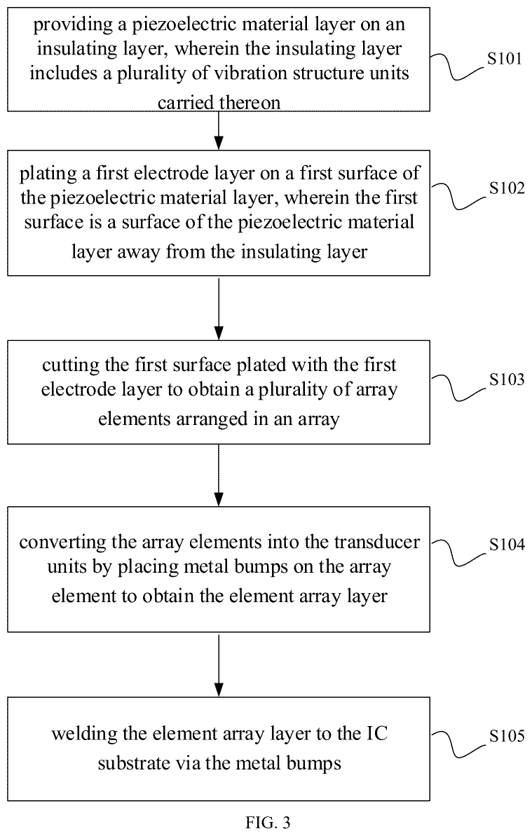

The present application further provides a method for preparing an ultrasonic transducer, the corresponding flowchart of which is shown in FIG. 3, and the method includes the following steps.

S101: providing a piezoelectric material layer 211 on an insulating layer 300, where the insulating layer 300 includes a plurality of vibration structure units 310 carried thereon.

In actual production, the insulating layer 300 is often received in the form of a large wafer. After receiving the large wafer, it is necessary to first plate a first electrode layer 212 on its surface, and then cut it into wafer blocks of the size required for a single ultrasonic transducer. The cut wafer blocks are bonded to the IC substrate 100.

It should be noted that the order of step S101 is not fixed, and the order of the following steps can be adjusted according to actual conditions, which is not limited by the present application.

S102: plating a first electrode layer 212 on a first surface of the piezoelectric material layer 211, where the first surface is a surface of the piezoelectric material layer 211 away from the insulating layer 300.

S103: cutting the first surface plated with the first electrode layer 212 to obtain a plurality of array elements arranged in an array.

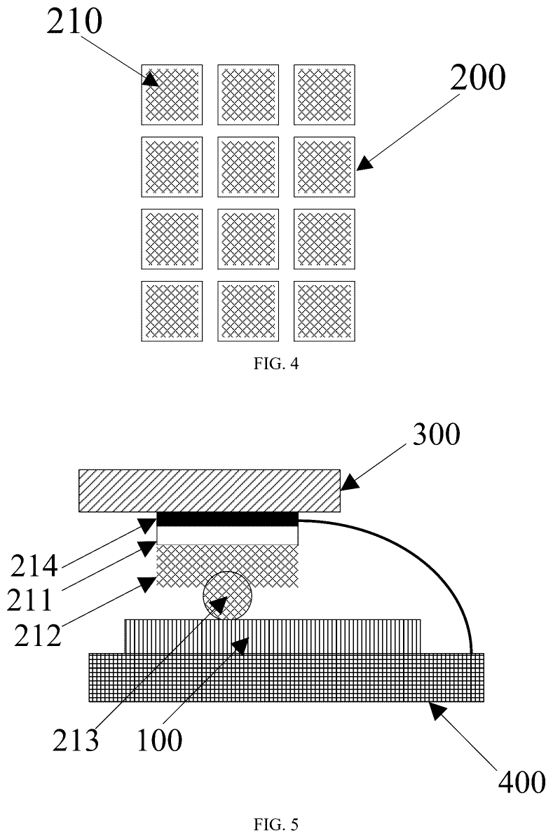

In combination with the above, the array element is the transducer unit 210 without the metal bump 213. After this step, the structure diagram of the plurality of array elements arranged in an array is shown in FIG. 4.

In this step, the first electrode layer 212 may be cut by only a portion of the piezoelectric material layer 211, that is, not completely cutting the piezoelectric material layer 211, or the piezoelectric material layer 211 may be completely cut. This can be adjusted according to actual conditions, but the first electrode layer 212 must be cut to form insulation between the array elements.

S104: converting the array elements into the transducer units 210 by placing metal bumps 213 on the array element to obtain the element array layer 200.

In this step, after all array elements are placed into the metal bumps 213, the array elements arranged in the entire layer constitute the element array layer 200.

S105: welding the element array layer 200 to the IC substrate 100 via the metal bumps 213.

After the metal bump 213 is welded to the IC substrate 100 in this step, it means that the upper electrode of the transducer unit 210 is connected to the IC. The lower electrode of the transducer unit 210 (the upper electrode is the positive electrode of the transducer unit 210 and the lower electrode is the negative electrode of the transducer unit 210) needs to be connected to the IC substrate 100, which will not be described in detail in the present application. After the transducer unit 210 is electrically connected to the IC substrate 100, a power-on check can also be performed to ensure that the connection is normal and the transducer unit 210 can work normally.

Furthermore, the metal bump 213 is connected to the IC substrate 100 by reflow soldering.

Reflow soldering can achieve precise soldering with a relatively small current, greatly reducing the possibility of damage to components during the soldering process, while reducing the possibility of cold soldering, thereby greatly improving the yield rate of finished products. Other soldering methods can also be selected according to actual needs, such as hot press soldering or hot air soldering, which are not limited in the present application.

The method for preparing an ultrasonic transducer in the embodiment corresponds to the ultrasonic transducer in the above description. The specific aggregation details can be referred to in the foregoing text, which will not be repeated here.

In an embodiment, the metal bump 213 on the array element is placed by at least one of the FCBGA process and the low-profile fine-pitch ball grid array (LFBGA) process. Accordingly, the metal bump 213 is a solder ball. The use of the above two ball grid placement processes can greatly shorten the time consumption for setting the metal bump 213 and improve production efficiency. The metal bump 213 can also be an indium column or other metal structure, and the placement method can also select other technical means according to actual needs, which is not limited in the present application.

In the method for preparing an ultrasonic transducer of the present application, the first electrode layer 212 is plated on the first surface of the piezoelectric material layer 211; the first surface plated with the first electrode layer 212 is cut to obtain a plurality of array elements arranged in an array; the array element is converted into a transducer unit 210 by placing a metal bump 213 on the array element to obtain an element array layer 200; the element array layer 200 is welded to the IC substrate 100 through the metal bump 213; and an insulating layer 300 is provided at the second surface of the piezoelectric material layer 211, and the insulating layer 300 includes a plurality of vibration structure units 310 configured for concentrating the energy of the vibration structure unit 310 as above mentioned. The plurality of vibration structure units 310 are provided with a plurality of back cavity grooves. Further, the number and distribution of the vibration structure units or the back cavity grooves are uniform to avoid creating new stress concentration points. The vibration structure units 310 or the back cavity grooves help reduce mechanical stress accumulation during the preparation of the ultrasonic transducer and while the ultrasonic transducer is operational, preventing the insulating layer 300 from bending or cracking. In the present application. the transducer unit 210 is flipped, and the first electrode layer 212 with the metal bump 213 is in turn directly contacted and welded with the IC substrate 100 below, which has a strong structure, simple process and low cost, meanwhile ensuring that the signal transmission path is the shortest, the interference is less, and the attenuation is lower, therefore the transmission reliability of the signal is greatly improved and the signal quality is greatly improved.

In this specification, each embodiment is described in a progressive manner, and each embodiment focuses on the differences from other embodiments. The same or similar parts between the embodiments can be referred to each other. For the device disclosed in the embodiment, since it corresponds to the method disclosed in the embodiment, the description is relatively simple, and the relevant parts can be referred to the method part.

It should be noted that, in this specification, relational terms such as “first” and “second”, etc., are only used to distinguish one entity or operation from another entity or operation, and do not necessarily require or imply any such actual relationship or order between these entities or operations. Moreover, the terms “comprise”, “include” or any other variants thereof are intended to cover non-exclusive inclusion, so that a process, method, article or device including a series of elements includes not only those elements, but also other elements not explicitly listed, or further includes elements inherent to such process, method, article or device. In the absence of further restrictions, the elements defined by the sentence “comprise a . . . ” do not exclude the presence of other identical elements in the process, method, article or device including the elements.

The ultrasonic transducer and the preparation method thereof provided by the present application are introduced in detail above. The principles and implementation methods of the present application are described in detail using specific examples herein, and the description of the above embodiments is only used to help understand the method and the core idea of the present application. It should be pointed out that for those skilled in the art, without departing from the principles of the present application, several improvements and modifications can be made to the present application, and these improvements and modifications also fall within the scope of protection of the claims of the present application.

What is claimed is:

1. An ultrasonic transducer, comprising:
an integrated circuit (IC) substrate;
an element array layer; and
an insulating layer;
wherein the IC substrate, the element array layer and the insulating layer are stacked in sequence; the element array layer comprises a plurality of transducer units;
the transducer unit comprises a first electrode layer and a piezoelectric material layer;
the transducer unit is welded and connected to the IC substrate via a metal bump carried on the first electrode layer; and
the insulating layer comprises a plurality of vibration structure units carried thereon.

2. The ultrasonic transducer according to claim 1, wherein the plurality of vibration structure units are provided with a plurality of back cavity grooves along a direction perpendicular to the element array layer; a dimension of the back cavity groove gradually decreases from an opening to a bottom of the back cavity groove.

3. The ultrasonic transducer according to claim 1, wherein the plurality of vibration structure units are spaced apart uniformly along a direction of the insulating layer.

4. The ultrasonic transducer according to claim 3, wherein the plurality of vibration structure units have a same shape, and a dimension of each vibration structure unit is identical along a direction perpendicular to the element array layer.

5. The ultrasonic transducer according to claim 1, further comprising:
a porous heat dissipation substrate;
wherein a surface of the IC substrate away from the metal bump is fixedly connected to the porous heat dissipation substrate.

6. The ultrasonic transducer according to claim 1, wherein the IC substrate is an application specific integrated circuit (ASIC) substrate.

7. The ultrasonic transducer according to claim 1, further comprising:
electronic insulating glue;
wherein the electronic insulating glue is filled between adjacent transducer units.

8. The ultrasonic transducer according to claim 1, further comprising:
an acoustic impedance matching layer;
wherein the acoustic impedance matching layer at least covers an outer surface of the insulating layer.

9. The ultrasonic transducer according to claim 8, wherein the acoustic impedance matching layer further comprises a conductive glue layer; and
the insulating layer is configured to insulate the element array layer from the conductive glue layer.

10. The ultrasonic transducer according to claim 1, wherein bottom electrodes of the plurality of transducer units are connected to the IC substrate via at least one of coaxial cables, gold wire bonding, and through silicon via direct connection.

11. A method for preparing an ultrasonic transducer, comprising:
providing a piezoelectric material layer on an insulating layer, wherein the insulating layer comprises a plurality of vibration structure units carried thereon;
plating a first electrode layer on a first surface of the piezoelectric material layer, wherein the first surface is a surface of the piezoelectric material layer away from the insulating layer;
cutting the first surface plated with the first electrode layer to obtain a plurality of array elements arranged in an array;
converting the array elements into the transducer units by placing metal bumps on the array elements to obtain an element array layer; and
welding the element array layer to an IC substrate via the metal bumps.

12. The method for preparing the ultrasonic transducer according to claim 11, wherein the metal bump is connected to the IC substrate by reflow soldering.
